(19) United States
(12) Patent Application Publication
(10) Pub. No.: US 2006/0273454 A1
(43) Pub. Date: Dec. 7, 2006

(54) Locking mechanism for die assembly

(76) Inventors: Daogiang Lu, Chandler, AZ (US); Hamid Eslampour, Phoenix, AZ (US); Edward R. Prack, Phoenix, AZ (US); Edward A. Zarbock, Gilbert, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/147,021

(22) Filed: Jun. 6, 2005

(51) Int. Cl. H01L 23/34

(52) U.S. Cl. 257/712

(57) ABSTRACT

Some embodiments of the present invention include locking mechanisms for die assembly.

### TECHNICAL FIELD

Embodiments of the invention relate to semiconductor packaging. In particular, embodiments of the invention relate to methods and apparatus for die and substrate assembly.

### BACKGROUND

After a microelectronic chip or die has been manufactured, it is typically packaged before it is sold. The package may provide electrical connection to the chip's internal circuitry, protection from the exterior environment, and heat dissipation. In one package system, a chip may be flip-chip connected to a substrate. In a flip-chip package, electrical leads on the die are distributed on its active surface and the active surface is electrically connected to corresponding leads on a substrate. An integrated heat spreader may also be attached to the die to dissipate heat.

In a flip chip package assembly process, an integrated heat spreader may first be attached to a die. The die and integrated heat spreader may then be picked and placed onto a substrate with leads on the die aligned to leads on the substrate. Next, the die, integrated heat spreader, and substrate may be transferred to a reflow oven where electrical connections are formed between the leads on the die and the leads on the substrate. In the transfer from pick and place module to reflow oven, the relatively heavy integrated heat spreader may cause the die and integrated heat spreader to move relative to the substrate during transfer. Such movement can cause misalignment and rejected units.

### BRIEF DESCRIPTION OF THE DRAWINGS

The invention is illustrated by way of example and not by way of limitation in the figures of the accompanying drawings, in which the like references indicate similar elements and in which:

FIGS. 1A-1D illustrate cross sectional type views of a method in accordance with one embodiment of the present invention.

FIGS. 2A-2D illustrate cross sectional type views of a method in accordance with one embodiment of the present invention.

FIG. 3 illustrates a schematic of a system in accordance with one embodiment of the present invention.

### DETAILED DESCRIPTION

In the following description, various embodiments relating to semiconductor package assembly will be described. However, various embodiments may be practiced without one or more of the specific details, or with other methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Various operations will be described as multiple discrete operations in turn. However, the order of description should not be construed as to imply that these operations are necessarily order dependent. In particular, these operations need not be performed in the order of presentation.

In semiconductor package assembly, rejected units may be reduced and process quality may be enhanced by locking or tacking a die and integrated heat spreader to a substrate after the die and substrate are aligned. In particular, the die and integrated heat spreader may be locked or tacked to the substrate using a re-meltable material. The locking or tacking may eliminate or reduce movement of the die relative to the substrate during transfer between process modules or when a clip is used to provide a normal force during electrical connection formation. During reflow, the re-meltable material may melt at a temperature below the reflow temperature to allow the die and substrate to collapse together for formation of electrical connections.

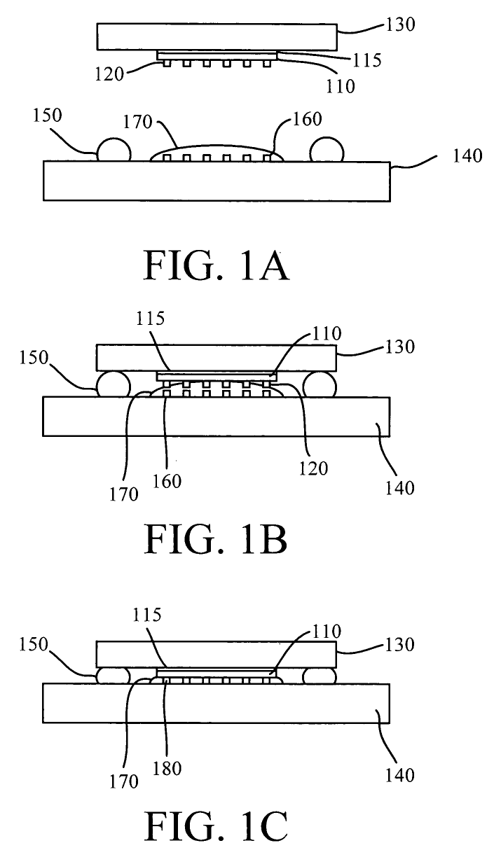

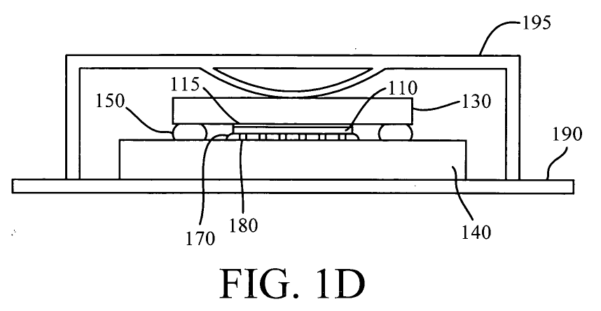

FIGS. 1A-1D illustrate a method and apparatus for locking or tacking a die and integrated heat spreader to a substrate.

FIG. 1A illustrates a cross sectional type view of a die 110, thermal interface material 115, contacts 120, integrated heat spreader 130, substrate 140, re-meltable material 150, contacts 160, and underfill material 170. Die 110 may include any suitable material, such as a semiconductor, monocrystalline Silicon, Silicon on insulator, or Gallium Arsenide. In an embodiment, die 110 may include layers and structures that include insulative, conductive, or semiconductive materials that form transistors and metal interconnect layers to provide an integrated circuit. In another embodiment, die 110 may be a thin die. In an embodiment, die 110 may have a thickness in the range of about 25 to 500 microns.

Contacts 120 may be formed by any suitable technique and may include any suitable material. In an embodiment, contacts 120 may include bumps. In an embodiment, contacts 120 may include Copper. In another embodiment, contacts 120 may include a solder. In an embodiment, contacts 120 may be distributed throughout an active surface of die 110. In an embodiment, the active surface may include transistors, metal interconnects, or other features that define an integrated circuit. Contacts 120 may extend away from a surface of die 110. However, in an embodiment, contacts 120 may include landing pads that do not extend from a surface of die 110. Die 110 may be attached to integrated heat spreader 130 by any suitable technique. In an embodiment, die 110 is attached to integrated heat spreader 130 by thermal interface material. In some embodiments, thermal interface material 115 may include a solder or a thermally conductive adhesive. In an embodiment, thermal interface material 115 may have a thickness in the range of about 5 to 200 microns. In an embodiment, die 110, thermal interface material 115, and integrated heat spreader 130 may be in a thin die and thin thermal interface material configuration. In another embodiment, the attached die 110 and integrated heat spreader 130 may be an integrated heat spreader/die assembly.

Substrate 140 and contacts 160 may be formed by any suitable technique and may include any suitable materials. In an embodiment, contacts 160 may include bumps. In an embodiment, contacts 160 may include Copper. In another embodiment, contacts 160 may include a solder. Contacts 160 may extend away from a surface of substrate 140. However, in an embodiment, contacts 120 may include landing pads that do not extend from a surface of substrate 140. In an embodiment, contacts 120 and contacts 160 may be patterned such that contacts 120 have corresponding contacts 160 that are aligned when die 110 and substrate 140 are aligned.

Underfill material 170 may be formed over contacts 160. Underfill material 170 may be any suitable material and may be formed by any suitable technique. In an embodiment, underfill material 170 may be a no-flow underfill material. In another embodiment, underfill material 170 may not be used.

Re-meltable material 150 may be placed on substrate 140. Re-meltable material 150 may be any suitable material. In an embodiment, re-meltable material 150 may include a thermoplastic. In another embodiment, re-meltable material 150 may include a thermoplastic oligomer or polymer. In an embodiment, re-meltable material 150 may include a thermoplastic paste, such as STAYSTIK 336T from Cookson Electronics. In another embodiment, re-meltable material 150 may include a re-meltable material dissolved in a solvent. In another embodiment, re-meltable material 150 may include a thermoplastic film, such as STAYSTIK 472 from Cookson Electronics or Thermo-Bond Film-620 from 3M. In an embodiment, re-meltable material 150 may include a solder. In another embodiment, re-meltable material 150 may include a solder with a melting point below about 200° C. In an embodiment, re-meltable material 150 may include a solder including Indium, Indium-Tin, or Indium-Bismuth. In an embodiment, re-meltable material 150 may include a thermal decomposable material such as Unity200, from Promerus, LLC. In an embodiment, re-meltable material 150 may include a thermal decomposable material that decomposes into gases at a temperature of about 200° C.

In an embodiment, re-meltable material 150 may be chosen such that it has a melting point below the reflow temperature of a solder chosen to electrically connect die 110 and substrate 140. In an embodiment, re-meltable material 150 may have a melting point in the range of about 160 to 200° C. In another embodiment, re-meltable material 150 may have a melting point in the range of about 120 to 180° C. In an embodiment, re-meltable material 150 may have a melting point in the range of about 180 to 220° C. In an embodiment, re-meltable material 150 may be chosen such that it has a melting point below the reflow temperature of a solder chosen to electrically connect die 110 and substrate 140. In an embodiment, re-meltable material 150 may be chosen such that it has a decomposition temperature below the reflow temperature of a solder chosen to electrically connect die 110 and substrate 140. In an embodiment, re-meltable material 150 may have decomposition temperature in the range of 180 to 200° C.

Although FIG. 1A illustrates re-meltable material 150 placed on substrate 140, re-meltable material 150 may be disposed between die 110 and substrate 140 by any suitable technique. In an embodiment, re-meltable material 150 may be placed on integrated heat spreader 130. In another embodiment, re-meltable material 150 may be disposed by applying it as a tape on substrate 140 or integrated heat spreader 130. Re-meltable material 150 may be arranged in any suitable way. In an embodiment, re-meltable material 150 may be arranged such that it is at one or more corners of integrated heat spreader 130. In an embodiment, re-meltable material 150 may be arranged such that it is along 2 edges of integrated heat spreader 130. In another embodiment, re-meltable material 150 may be arranged such that it runs around the perimeter of integrated heat spreader 130.

As illustrated in FIG. 1B, die 110 and substrate 140 may be joined together and secured by re-meltable material 150. In an embodiment, die 110 and integrated heat spreader 130 may be picked and placed onto re-meltable material 150. In an embodiment, contacts 160 and contacts 120 may be aligned. FIG. 1B illustrates re-meltable material 150 holding contacts 160 and contacts 120 slightly apart and contacts 120 slightly penetrating underfill material 170. However, re-meltable material 150 may hold integrated heat spreader 130 and substrate 140 in any suitable position. In an embodiment, contacts 120 may not penetrate underfill material 170. In another embodiment, some or all of contacts 160 and contacts 120 may be touching.

In an embodiment, re-meltable material 150 may lock or tack die 110 and integrated heat spreader 130 to substrate 140. In an embodiment, re-meltable material 150 may secure die 110 and integrated heat spreader 130 and substrate 140 together during transfer between process steps. In an embodiment, re-meltable material 150 may secure die 110 and integrated heat spreader 130 and substrate 140 together during transfer between a pick and place module and a reflow oven. In an embodiment, re-meltable material 150 may secure die 110 and integrated heat spreader 130 and substrate 140 together during transfer on a conveyer.

In an embodiment, re-meltable material 150 may be hardened by heating to dry out a solvent. In an embodiment, re-meltable material may be heated at a temperature in the range of about 60 to 80° C.

In an embodiment, as illustrated in FIG. 1C, electrical connections 180 may be formed between die 110 and substrate 140. In an embodiment, a reflow process may be performed to form electrical connections 180. In an embodiment, electrical connections 180 may be C4 joints. In another embodiment, electrical connections 180 may be solder joints. In an embodiment, during reflow, re-meltable material 150 may melt at a temperature less than the reflow temperature. In an embodiment, melting re-meltable material 150 may allow die 110 and substrate 140 to collapse together.

In an embodiment, an underfill cure may be performed to cure underfill material 170. In an embodiment, a sealant (not shown) may be applied and a sealant cure may be performed. In another embodiment, re-meltable material 150 may act as a sealant and an optional cure may be performed.

In an embodiment, as illustrated in FIG. 1D, electrical connections 180 may be formed between die 110 and substrate 140 with the use of a clip 195 attached to a carrier 190. In an embodiment, clip 195 may provide a normal force for bonding forming electrical connections 180. In an embodiment, die 110 and integrated heat spreader 130 may not shift relative to substrate 140 because they are secured by re-meltable material 150. In an embodiment, the apparatus of FIG. 1D may be reflowed to form electrical connections 180. In an embodiment, during reflow, re-meltable material 150 may melt at a temperature less than the reflow temperature. In an embodiment, melting re-meltable material 150 may allow die 110 and substrate 140 to collapse together.

In an embodiment, clip 195 may be released and substrate 140 may be removed from carrier 190. In an embodiment, an underfill cure may be performed to cure underfill material 170. In an embodiment, a sealant (not shown) may be applied and a sealant cure may be performed. In another embodiment, re-meltable material 150 may act as a sealant and an optional cure may be performed.

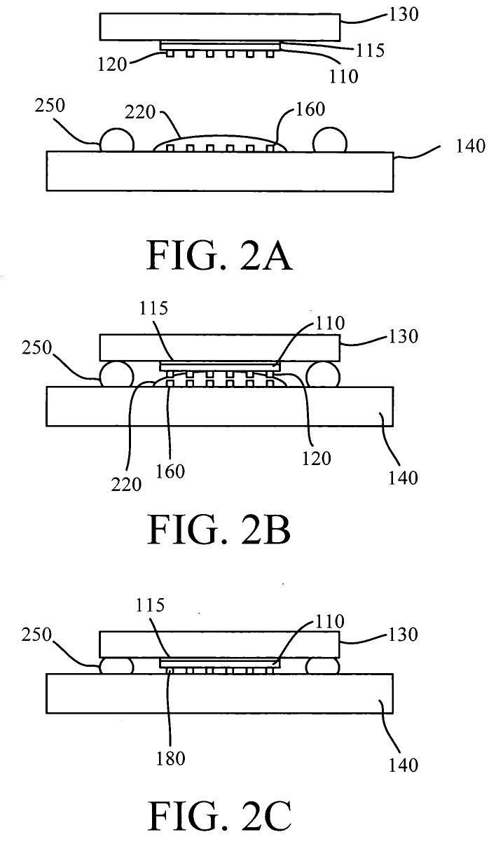

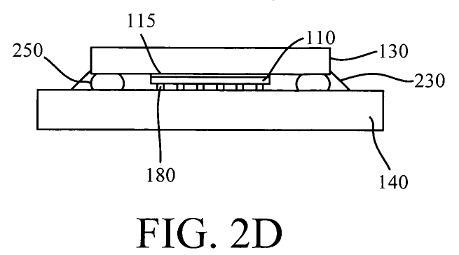

FIGS. 2A-2D illustrate a method and apparatus for locking or tacking a die and integrated heat spreader to a substrate.

FIG. 2A illustrates a cross sectional type view of a die 110, thermal interface material 115, contacts 120, integrated heat spreader 130, substrate 140, re-meltable material 250, contacts 160, and flux 220. As discussed above, die 110, contacts 120, substrate 140, and contacts 160 may be any suitable materials formed by any suitable technique. Also, die 110 may be attached to integrated heat spreader 130 by any suitable technique.

Flux 220 may be formed over contacts 160. Flux 220 may be any suitable material and may be formed by any suitable technique. In an embodiment, flux 220 may be a no-clean flux. In an embodiment, flux 220 may not be required.

Re-meltable material 250 may be formed on substrate 140. Re-meltable material 250 may be any suitable material. In an embodiment, re-meltable material 250 may include a thermoplastic. In another embodiment, re-meltable material 250 may include a thermoplastic oligomer or polymer. In an embodiment, re-meltable material 250 may include a thermoplastic paste, such as STAYSTIK 336T from Cookson Electronics. In another embodiment, re-meltable material 250 may include a re-meltable material dissolved in a solvent. In another embodiment, re-meltable material 250 may include a thermoplastic film, such as STAYSTIK 472 from Cookson Electronics or Thermo-Bond Film-620 from 3M. In an embodiment, re-meltable material 250 may include a solder. In another embodiment, re-meltable material 250 may include a solder with a melting point below about 200° C. In an embodiment, re-meltable material 250 may include a solder including Indium, Indium-Tin, or Indium-Bismuth. In an embodiment, re-meltable material 150 may include a thermal decomposable material such as Unity200, from Promerus, LLC. In an embodiment, re-meltable material 150 may include a thermal decomposable material that decomposes into gases at a temperature of about 200° C.

In an embodiment, re-meltable material 250 may be chosen such that it has a melting point below the reflow temperature of a solder chosen to electrically connect die 110 and substrate 140. In an embodiment, re-meltable material 250 may have a melting point in the range of about 160 to 200° C. In another embodiment, re-meltable material 250 may have a melting point in the range of about 120 to 180° C. In an embodiment, re-meltable material 250 may have a melting point in the range of about 180 to 220° C. In an embodiment, re-meltable material 150 may be chosen such that it has a decomposition temperature below the reflow temperature of a solder chosen to electrically connect die 110 and substrate 140. In an embodiment, re-meltable material 150 may have decomposition temperature in the range of 180 to 200° C.

Although FIG. 2A illustrates re-meltable material 250 formed on substrate 140, re-meltable material 250 may be disposed between die 110 and substrate 140 by any suitable technique. In an embodiment, re-meltable material 250 may be formed on integrated heat spreader 130. In another embodiment, re-meltable material 250 may be formed by applying it as a tape on substrate 140 or integrated heat spreader 130. Re-meltable material 250 may be arranged in any suitable way such that a subsequent capillary underfill material may be disposed between die 110 and substrate 140, as is further discussed below. In an embodiment, re-meltable material 250 may be arranged near one or more corners of integrated heat spreader 130. In an embodiment, re-meltable material 250 may be arranged along 2 edges of integrated heat spreader 130.

Die 110 and substrate 140 may be joined together and secured by re-meltable material 250. In an embodiment, die 110 and integrated heat spreader 130 may be picked and placed onto re-meltable material 250. Contacts 160 and contacts 120 may be aligned. FIG. 2B illustrates re-meltable material 250 holding contacts 160 and contacts 120 slightly apart and contacts 120 slightly penetrating flux 220. However, re-meltable material 250 may hold integrated heat spreader 130 and substrate 140 in any suitable position. In an embodiment, contacts 120 may not penetrate flux 220. In another embodiment, some or all of contacts 160 and contacts 120 may be touching.

In an embodiment, re-meltable material 250 may be hardened by heating to dry out a solvent. In an embodiment, re-meltable material may be heated at a temperature in the range of about 60 to 80° C.

In an embodiment, re-meltable material 250 may lock or tack die 110 and integrated heat spreader 130 to substrate 140. In an embodiment, re-meltable material 250 may secure die 110 and integrated heat spreader 130 and substrate 140 together during transfer between process steps. In an embodiment, re-meltable material 250 may secure die 110 and integrated heat spreader 130 and substrate 140 together during transfer between a pick and place module and a reflow oven. In an embodiment, re-meltable material 250 may secure die 110 and integrated heat spreader 130 and substrate 140 together during transfer on a conveyer.

As illustrated in FIG. 2C, electrical connections 180 may be formed between die 110 and substrate 140. In an embodiment, a reflow process may be performed to form electrical connections 180. In an embodiment, electrical connections 180 may be C4 joints. In an embodiment, during reflow, re-meltable material 250 may melt at a temperature less than the reflow temperature. In an embodiment, melting re-meltable material 150 may allow die 110 and substrate 140 to collapse together.

As illustrated in FIG. 2D, an underfill material 230 may be provided. In an embodiment, underfill material 230 may include a capillary underfill material. In an embodiment, underfill material 230 may be provided by introducing it along an edge of integrated heat spreader 130. In another embodiment, underfill material 230 may be provided by introducing it along two edges of integrated heat spreader 130. As illustrated, underfill material 230 may be disposed between die 110 and substrate 140 and between integrated heat spreader 130 and substrate 140. However, underfill material 230 may be disposed in any suitable way. In an embodiment, underfill material 230 may be disposed only between die 110 and substrate 140.

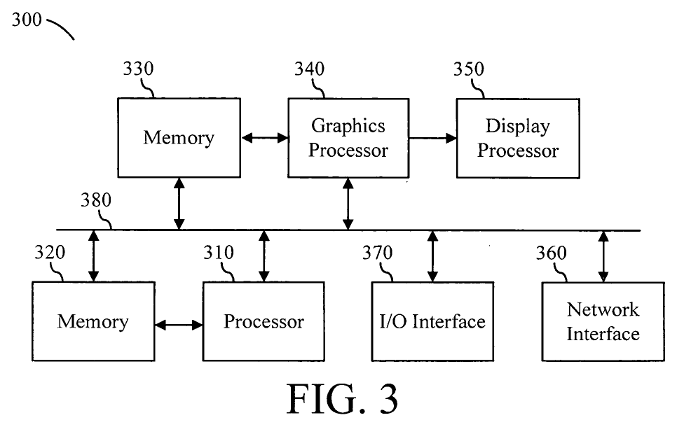

As illustrated in FIG. 3, the re-meltable material discussed above may be incorporated into a system 300. System 300 may include a processor 310, a memory 320, a memory 330, a graphics processor 340, a display processor 350, a network interface 360, an I/O interface 370, and a communication bus 380. In any manner as described above, any of the components in system 300 may include re-meltable material in a bond between a component chip or die and a substrate or motherboard. In an embodiment, processor 310 may include a re-meltable material. In another embodiment, graphics processor 340 may include a re-meltable material. In another embodiment, memory 320 may be a volatile memory component and may include a re-meltable material. A large number of combinations of components including a re-meltable material may be available.

Reference throughout this specification to “one embodiment” or “an embodiment” technique that a particular feature, structure, material, or characteristic described in connection with the embodiment is included in at least one embodiment of the invention. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

What is claimed is:

1. A method comprising:
placing a re-meltable material between an integrated heat spreader of an integrated heat spreader/die assembly and a substrate; and
securing the integrated heat spreader/die assembly and the substrate by the re-meltable material.

2. The method of claim 1, wherein the re-meltable material comprises at least one of a thermoplastic oligomer, polymer, paste, or film.

3. The method of claim 1, wherein the re-meltable material comprises a solder including at least one of Indium, Indium-Tin, or Indium-Bismuth.

4. The method of claim 1, wherein the re-meltable material is along two edges of the integrated heat spreader.

5. The method of claim 1, wherein the re-meltable is at four corners of the integrated heat spreader.

6. The method of claim 1, wherein the re-meltable is around the perimeter of the integrated heat spreader.

7. The method of claim 1, wherein securing the integrated heat spreader/die assembly to the substrate includes aligning a bump on the die with a bump on the substrate.

8. The method of claim 1, further comprising:
transferring the integrated heat spreader/die and the substrate.

9. The method of claim 1, further comprising:
performing a reflow to form an electrical connection between the die and the substrate.

10. The method of claim 9, wherein performing the reflow process includes decomposing the re-meltable material and forming the electrical connection at a temperature above the decomposition temperature of the re-meltable material.

11. The method of claim 9, wherein performing the reflow process includes melting the re-meltable material and forming the electrical connection at a temperature above the melting point of the re-meltable material.

12. The method of claim 11, wherein melting the re-meltable material causes the die and the substrate to collapse together.

13. The method of claim 12, further comprising:
drying the re-meltable material; and
placing a clip on the integrated heat spreader to provide a bonding pressure.

14. The method of claim 13, wherein placing the re-meltable material between the integrated heat spreader/die assembly and substrate includes disposing the re-meltable material on the substrate as a paste and drying the re-meltable material at a temperature in the range of about 60 to 80° C.

15. The method of claim 1, further comprising:
providing a no-flow underfill material between the die and the substrate.

16. The method of claim 1, further comprising:
providing a capillary underfill material between the die and the substrate by introducing the capillary underfill material along an edge of the integrated heat spreader.

17. A method comprising:
placing a re-meltable material between an integrated heat spreader of an integrated heat spreader/die assembly and a substrate; and
securing the integrated heat spreader/die assembly to the substrate by the re-meltable material;
transferring the integrated heat spreader/die and the substrate; and
performing a reflow to form an electrical connection between the die and the substrate.

18. The method of claim 17, wherein the re-meltable material comprises at least one of a thermoplastic oligomer, polymer, paste, or film.

19. The method of claim 17, wherein placing the re-meltable material between the integrated heat spreader and the substrate includes disposing the re-meltable material on the substrate, and securing the integrated heat spreader/die assembly to the substrates includes performing a pick and place to align the die and the substrate.

20. The method of claim 17, wherein performing the reflow process includes melting the re-meltable material at a melting temperature and reaching a reflow temperature above the melting temperature to form the electrical connection.

21. The method of claim 17, further comprising:
drying the re-meltable material; and
placing a clip on the integrated heat spreader to provide a bonding pressure.

22. The method of claim 17, further comprising:
disposing a no-flow underfill material between the die and the substrate.

23. The method of claim 17, further comprising:
disposing a capillary underfill material between the die and the substrate.

24. An apparatus comprising:
an active surface of a die attached to a substrate by electrical connections;
an integrated heat spreader attached to a surface of the die opposite the active surface;
a re-meltable material between the integrated heat spreader and the substrate; and
an underfill material between the die and the substrate.

25. The apparatus of claim 24, wherein the re-meltable material comprises at least one of a thermoplastic oligomer, polymer, paste, or film.

26. The apparatus of claim 24, wherein the re-meltable material comprises a solder including at least one of Indium, Indium-Tin, or Indium-Bismuth.

27. The apparatus of claim 24, wherein the re-meltable material is along two edges of the integrated heat spreader.

28. The apparatus of claim 24, wherein the re-meltable material is at four corners of the integrated heat spreader.

29. The apparatus of claim 24, wherein the underfill material comprises a no-flow underfill material.

30. The apparatus of claim 24, wherein the underfill material comprise a capillary underfill material.

31. The apparatus of claim 24, further comprising:
a sealant between the integrated heat spreader and the substrate.

32. A system comprising:
a microprocessor flip chip bonded to a substrate;
an integrated heat spreader attached to the microprocessor;
a re-meltable material between the integrated heat spreader and the substrate;
an underfill material between the microprocessor and the substrate; and
a display processor.

33. The system of claim 32, further comprising:
a volatile memory component.
